(19) United States
(12) Patent Application Publication
(10) Pub. No.: US 2024/0136783 A1
(43) Pub. Date: Apr. 25, 2024

(54) METHOD AND DEVICE FOR INCREASING USEFUL LIFE OF LASER SYSTEM

(71) Applicant: IPG PHOTONICS CORPORATION, Marlborough, MA (US)

(72) Inventors: Alexey Avdokhin, Marlborough, MA (US); Nikolai Platonov, Marlborough, MA (US); Pankaj Kadwani, Marlborough, MA (US); Jimyung Kim, Marlborough, MA (US)

(73) Assignee: IPG PHOTONICS CORPORATION, Marlborough, MA (US)

(21) Appl. No.: 18/568,013

(22) PCT Filed: Jun. 7, 2022
(86) PCT No.: PCT/US2022/032619

§ 371 Date: Dec. 7, 2023

Related U.S. Application Data
(60) Provisional application No. 63/208,289, filed on Jun. 8, 2021.

(51) Int. Cl. H01S 3/10; H01S 3/00; H01S 3/04; H01S 3/23

(52) U.S. Cl. CPC H01S 3/1001; H01S 3/0092; H01S 3/0405; H01S 3/10069; H01S 3/2316; H01S 3/09415

(57) ABSTRACT

A laser system is configured with at least one light amplifying device sequentially outputting a light signal at first and at least one additional operating wavelengths over respective time intervals. Each time interval is shorter than the predetermined lifespan of the light amplifying device. The total useful life of the light amplifying device, operating at a plurality of wavelengths, is 3-10 times longer than the predetermined lifespan.

### FIELD OF THE DISCLOSURE

The present disclosure relates to laser systems having at least one solid-state amplifier or booster. In particular, the disclosure relates to a laser system in which the booster is controllable to sequentially operate at multiple wavelengths for respective time intervals each of which is shorter than the predetermined lifetime of the booster at any of the multiple wavelengths.

### BACKGROUND OF THE DISCLOSURE

For many entities, capital assets represent a significant investment of resources. As such, to make the most of the investment, these assets need to be actively accounted for and managed. Depreciation is “the systematic and rational allocation of the acquisition cost of an asset, less its estimated salvage value or residual value, over the assets estimated useful life.” See https://www.investopedia.com/terms.asp. Simply said, it is a way of allocating a portion of the cost of a fixed asset over the period it can be used. “Useful life is an estimate of the average number of years an asset is considered useable before its value is fully depreciated,” Id “Fixed asset is an item, such as equipment, a company plans to use over the long-term to help generate income.” Id

It is helpful for a manufacturer to consider an assets current condition, the quality of the asset, or how the asset will be used when estimating its useful life also known as lifespan. But what is the useful life of a computer? How about an automobile? What about a TV? And most importantly for the subject matter patent application, what is the useful life of a laser? Here are some examples of the useful life estimates recommended by the US government (http://www.irs.gov/irm/part1/irm_01-035-006.html.)

TABLE I

| CATEGORY | DESCRIPTION | USEFUL LIFE |
|---|---|---|
| equipment | Computers | 5 |
| equipment | engineering equipment | 10 |
| equipment | audiovisual equipment | 10 |
| vehicles | general automobile | 8 |

Considering a variety of solid-state lasers including, among others fiber lasers, the cost of each individual device, of course, varies vastly depending on a configuration, output power, operational regime, signal wavelength and many other factors and parameters. However, a solid state laser operating, for example, in as a quasi-continuous (QCW) regime at the average power of several hundred of watts, does not come cheap. No wonder then that any customer/user, regardless of its size, is very much interested in the longevity of the purchased device/system. As to the manufacturer, surely, its very nature is to sell as many devices as possible; however, the favorable reputation and clientele of the manufacturer—goodwill—is undeniably a very important intangible asset of any business. In summary, the useful life of lasers is critical for both the manufacturer and customer.

Factors that may increase the useful life of a fixed asset include, among others, upgrading and regularly maintaining the fixed asset, improving maintenance procedures, technological advances, and revision of operating procedures. The following description relates to an exemplary fiber laser and fiber laser system of respective FIGS. 1 and 2A-2B, but as one of ordinary skill readily realizes the following description relates to any solid-state laser operating in any of continuous wave (CW), QCW or pulsed regimes.

FIGS. 2A-2B illustrate an exemplary optical schematic and assembled pulsed green nanosecond fiber laser system 10, respectively, which are disclosed in detail in U.S. Pat. No. 10,520,790 incorporated herein in its entirety by reference. The system 10 of FIG. 2 includes a module 12 and a laser head 14.

The module 12 houses, among other components, a pulsed master oscillator power fiber amplifier (MOPFA) laser source (FIG. 2A) outputting a train of IR light pulses through focusing optics at a 1064 nm fundamental wavelength set by the seed. The MOPFA configuration necessarily includes a seed 16 and a solid-state booster 18 such as a fiber amplifier. Additional components mounted in module 12 include electronics, preamplifiers, optical pumps, thermoelectric cooler controlling the temperature of the seed and others. The laser head 14 encloses a second harmonic frequency generator based on a non-linear crystal which converts IR light at a fundamental wavelength 1064 nm to green light at a 532 nm wavelength. It further houses light guiding optics and a spectral filter for separating unconverted IR light from green light.

The operation of system 10 includes a variety of indicators pointing out at how well system 10 functions. Practically each of the system's components is associated with a certain parameter that is typically monitored and controlled. From the customer's standpoint, the most important parameters of system 10 are the system's output power and spectral, temporal and/or spatial quality of light, if needed.

FIG. 3 illustrates the output of system 10 over the operation period measured in hours. As can be seen, the total IR power degrades at about 35% in about 350 hours. Over the same period of time the degradation of green power is about 46%. One of ordinary skill in the laser arts trying to identify the cause of such significant degradation would be able to entertain innumerous reasons. However, as a rule, the most probable culprit is the fiber booster. The cost of the booster of system 10 may reach tens of and even hundreds of thousands of dollars. If it fails, the only way to fix entire system 10, the cost of which may exceed several hundreds of thousands of dollars, is to replace the booster in its entirety.

Among a variety of reasons which may explain the booster's failure, one of the most plausible causes is based on a thermally written longitudinal index grating and associated therewith photo-darkening effect. The photo-darkening refers to a process when any object becomes non-transparent (dark) due to illumination with light. Recent papers use this term meaning reversible creation of absorbing color centers in optical fibers. These centers increase losses and decrease light quality. Other factors contributing to the booster's degradation may include the quantum defect and background absorption. Obviously, the useful life of the fiber booster may be somewhat longer than that of FIG. 3 and may reach about 2000 hours if the used fiber was characterized by high quality and thus had a higher photodarkening threshold. Typically, however, a booster incorporated in system 10 lasts no longer than 500 hundred hours.

FIG. 4 illustrates the Yb booster's emission spectrum. The dash line 18 indicates the desired spectrum having an inverted parabolic curve without valleys. And for a while, one may enjoy the smoothness of the curve indicating that the tested system operates in the desired manner. But it does not last long. At a certain point of time T₃, light experiences considerable losses, as indicated by the valley in measured spectrum 20.

FIG. 5 summarizes the above discussion. Specifically, at time T₃, further referred to as a time threshold, the power starts irreversibly decreasing. Shortly after it happens, the booster should be replaced. So, what is the useful life of the booster? it is certainly shorter than that of the products disclosed in the Table above. The known practice of dealing with the degradation of the booster includes operating the booster until the end of the useful life and then replacing it.

While the above description concentrates generally on a laser system including at least one amplifier, one of ordinary skill in the laser art readily realizes that other light amplifying devices, such as standalone oscillators experience the same problems. For example, it is not unusual for a standalone fiber oscillator of FIG. 1 to output several hundred of watts and sometime even a kilowatt. In many laser-based applications requiring either a single mode (SM) or multimode (MM) narrow linewidth or SM single frequency (SMSF) output, such a high power output would be perfectly adequate to perform the task at hand without employing additional amplifiers. However, like amplifiers incorporated in laser systems, the high power standalone oscillator may only benefit from the increased useful life.

Based on the foregoing, a need exists for a method and structural assembly that increase the lifetime of light amplifying devices used alone or incorporated in laser systems.

### SUMMARY OF THE DISCLOSURE

In accordance with the inventive concept of the disclosure, at least one laser is operable to output sequentially a light signal at a plurality of operating wavelengths for respective time intervals. Each interval terminates before the laser reaches the predetermined time threshold. Numerous experiments have shown that the laser operating in accordance with the disclosed concept is in use 3-10 times longer than the same booster as used in accordance with the known practice, i.e., at one single wavelength. The inventive concept can be implemented in a standalone light amplifying oscillator or laser system including in addition to the oscillator at least one amplifier.

The standalone laser is configured as an oscillator operative to sequentially output light at different wavelengths within the desired spectral range. Generally, any tunable laser operates this way. However, in contrast to the tunable oscillator, the inventive concept requires that a time interval at which the oscillator operates at each discreet wavelength be shorter than the empirically determined useful life at this wavelength.

Typically, high power laser systems provided with the MOP(F)A architecture, the main longevity concern relates to a booster—the last and most powerful amplifying cascade in a group of amplifiers providing light with the largest gain. The exemplary laser system thus includes a seed—master oscillator—outputting a light signal at a first operating wavelength which is selected from a plurality of operating wavelengths of the desired spectral range at which the seed can lase. The light signal is coupled either directly or after sequential gradual amplification into the booster. The system operates at the first wavelength over a first time interval. In accordance with the inventive concept, the first time interval is shorter than a predetermined lifespan of the booster at the first wavelength.

The seed is then tuned to output the light signal at a second operating wavelength selected from the spectral range for the second time interval. The second and subsequent time intervals, which correspond to respective operating wavelengths, each are shorter than the predetermined lifespan of the booster. Typically, the predetermined lifespan of the booster at any of the selected operating wavelengths is substantially the same. However, the possibility of the booster having the useful life which varies among the selected wavelengths is not excluded from the scope of this invention. In this case, time intervals for respective selected wavelengths may not be uniform, but the concept remains intact: each time interval is shorter than the predetermined lifespan of the booster at any given wavelength. The inventive concept allows the booster to operate for a considerably longer useful life while outputting a signal at the output power which remains within a predetermined narrow power range. Typically, the latter is ±5-10% of the maximum output power.

The inventive laser and laser system further includes a thermo-electric cooler (TEC) configured to control the temperature of the oscillator and more precise the temperature of Bragg Gratings (BG) causing the shift of the operating wavelength within the selected range. In the laser system with a MOPA configuration, the oscillator functions as a seed which typically is a laser diode. However, other configurations of the seed, such as a fiber oscillator, are part of the present invention.

In accordance with one configuration, the TEC operates based on a calibrated table establishing the relationship between the temperatures and respective operating wavelengths. The table is stored in the memory device of a controller.

Alternatively, the controller is configured with a continuously optimizing algorithm responsible for uninterruptedly controlling the temperature of the TEC. In contrast, in the table-based configuration the temperature changes in a discrete stepwise manner. Thus the inventive concept can be applied to both a discrete mode relying on the calibrated table and a continuous mode in which a wavelength is continuously changing without tracking of the exact wavelength in a given spectral band.

In addition to or alternatively to the temperature controllable configurations, the switching among wavelengths can be realized by controlling the input current applied to the seed if the latter has a semiconductor structure.

The disclosed method establishes the operation of the inventive laser system. In particular, it includes operating the seed at a plurality of operating wavelengths in a sequential manner. The duration of operation of the seed at each operating wavelength is controlled to be shorter than the predetermined useful life of the booster.

### BRIEF DESCRIPTION OF THE DRAWINGS

Various features of the inventive system and method will become more apparent in light of the accompanying figures, which are not intended to be drawn to scale. The figures constitute a part of the subject matter application, but are not intended as a definition of the limits of any particular embodiment. In the figures, each identical or nearly identical component shown in various figures is represented by a like numeral. For purposes of clarity, not every component may be labeled in every figure. In the figures:

FIG. 1 illustrates an exemplary stand-alone oscillator;

FIG. 2A illustrates the optical schematic of an exemplary fiber laser system provided with a frequency converter;

FIG. 2B illustrates the exemplary fiber laser system of FIG. 2A;

FIG. 3 illustrates the IR and Green powers distribution over time in the laser system of FIGS. 1 and 2;

FIG. 4 illustrates the spectral power output of the booster of the laser system of FIGS. 1 and 2;

FIG. 5 diagrammatically illustrates the operation of the booster of FIG. 4;

FIG. 6 diagrammatically illustrates the inventive concept of the disclosed laser system:

FIG. 7 illustrates an exemplary optical schematic of the inventive laser system;

FIG. 8 shown the IR and Green power distribution over the useful life of the inventive laser system;

FIG. 9 illustrates the spectral power output of the inventive system of FIG. 7; and

FIG. 10 illustrates the distribution of the IR power of the laser system of FIG. 7.

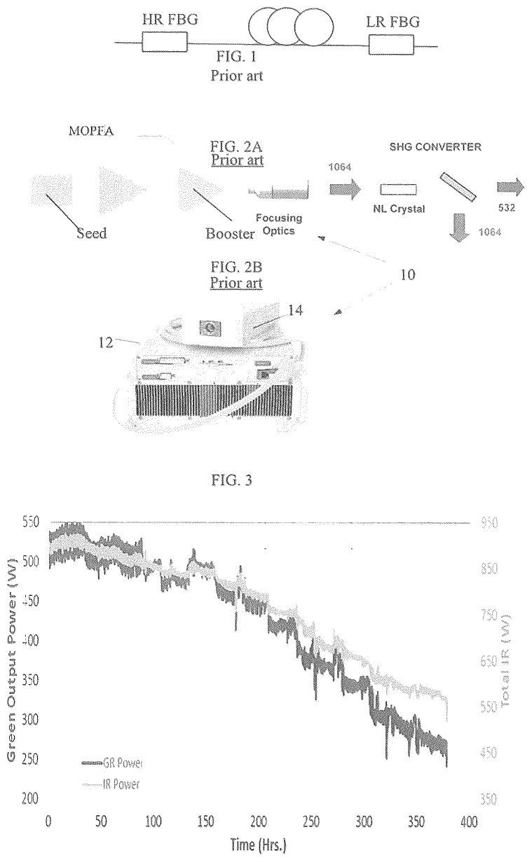

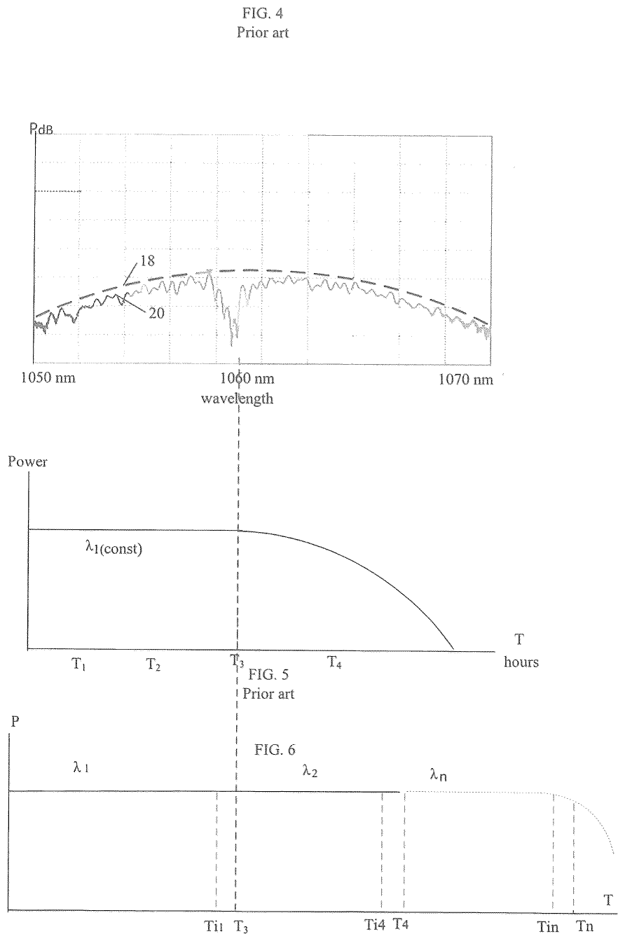

### SPECIFIC DESCRIPTION

The inventive concept allows a stand-alone laser or amplifier of laser system to operate 3-10 times longer than the lifespan of the same system having a standard configuration. The operation of the laser system in accordance with any given specification includes providing the output power within a specified range limited to ±10% of the specified output power. Preferably, this power range is limited to ±5-10% of the specified output power.

In contrast to the known art shown in FIG. 5 which illustrates a light amplifying device operating at a single wavelength during its entire lifespan, the inventive concept, as illustrated in FIG. 6, provides shifting the operating wavelength λᵢ₁ to λ₂ (to λₙ) prior to the termination of the lifespan of either the standalone laser or system's amplifier. Assuming that time intervals 0-T₃ and T₃-T₄, respectively each are equal to the predetermined lifespan, the light amplifying device is switched to a new wavelength at the end of time intervals (0-Tᵢ₃) and (Tᵢ₃-Tᵢ₄), respectively each of which is shorter than the predetermined lifespan, as explained below.

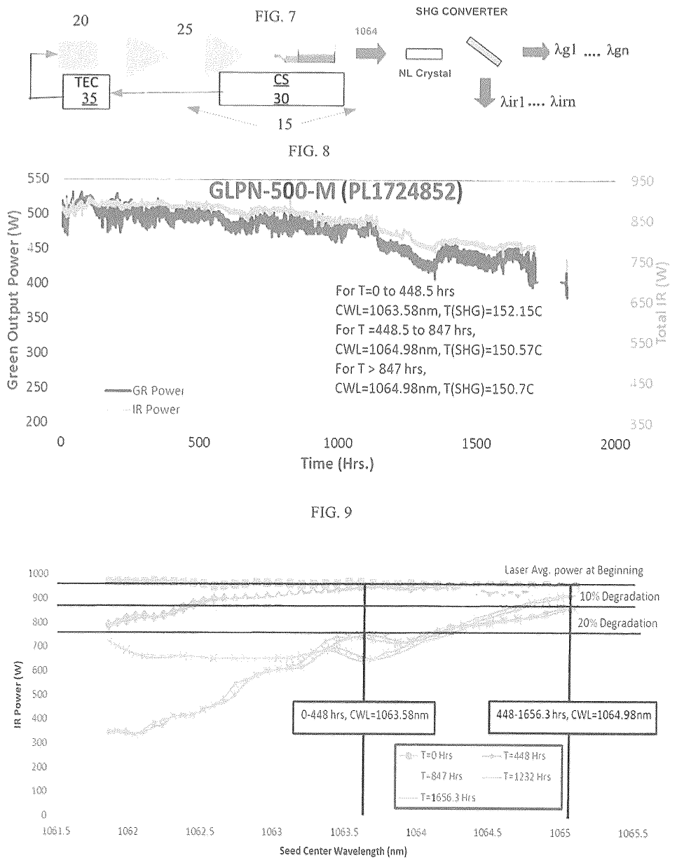

Considering FIG. 7 in addition to FIG. 6, the inventive concept is explained in detail based on a laser system IS. In particular, the exemplary schematic has a MOP(F)A architecture in accordance with which a seed 20 generates light signals at respective different operating wavelengths which are sequentially coupled into a booster 25. The systems with the MOPA configuration are primarily concerned with the longevity of the booster which has a useful life substantially shorter than that of a seed 20. The seed 20 is preferably a laser diode outputting a weak signal which is sequentially amplified in optional amplifying cascades including shown booster 25. The configuration of seed 20 is not limited to laser diodes and may include one of narrow linewidth, wavelength tunable/not-tunable, fiber, solid state, and single frequency lasers.

The booster 25 operates for a certain time interval at each of the coupled operating wavelengths. The condition which booster 25 has to meet includes terminating its operation at any of the selected operating wavelength before the known time threshold, which is the booster's lifespan, is reached. The booster 25, like seed 20, may have various configurations selected from, among others, narrow linewidth, single frequency, wavelength tunable, wavelength non-tunable, fiber, solid state and hybrid amplifiers.

The exemplary system 15 has a configuration similar to that of system 10 of FIG. 2B, however, die to its structural particularities, the original system components are capable of providing additional structural features which include periodic switching of seed 20 among numerous operating wavelengths. The operating wavelengths are selected from a spectral range in which seed 20 operates. The spectral range depends on a laser configuration and type of dopants. For example, the spectral range of a thulium (Tm) fiber laser may be as broad as approximately 200 nm, whereas solid state and fiber lasers doped with ytterbium (Yb) have a substantially narrower spectral range. If the latter is used, an exemplary spectral range is about 10 nm.

The seed 20 of system 15 includes a single mode (SM) diode laser operating at a single frequency. In general, the operating wavelength of the laser diode's output is shifted by altering the temperature of and/or current at the input of the laser diode. This is extremely evident with IR laser diodes where small changes in temperature greatly affect the small band gaps. Thus almost all laser diodes are temperature tunable, though this tunability is generally small. Laser diodes also display some current-based power tunability by altering the input current, but it is less preferable than the temperature-based tunability. The inventive concept can successfully work in laser systems configured with seed 20 which outputs radiation in a single or multiple transverse and longitudinal modes (MM).

Control system (CS) 30 of laser system 15 monitors the duration of each of the time intervals and, at the end thereof, generates a control signal coupled into a thermoelectric cooler (TEC) 35. In response to the control signal, TEC 35 alters the temperature of seed 20 causing thus the latter to operate at another operating wavelength different from the one used immediately before.

The system 15 incorporating the inventive structure operates in the following manner. Assume booster 25 (FIG. 7) of system 15 has a lifespan covering a 0-T₃ time period, as shown in FIG. 6, with T₃ being a time threshold. Before the booster's operation at a first operating wavelength λ₁ reaches time threshold T₃, CS 30 outputs a control signal at any time Tᵢ₁ shorter than T₃ time threshold. The control signal enables TEC 35 to alter the temperature of seed 20 which generates the light signal at a new operating wavelength λ₂. The operation of seed 20 at new wavelength λ₂ lasts over a time interval Tᵢ₁e-Tᵢ₂ which may or may not have the same duration as the first time interval 0-Tᵢ₁, but which is necessarily shorter than the lifespan of booster 25. The latter continues to receive one or more light signals from seed 20 at respective different operationing wavelengths λₙ over respective uniform or non-uniform time intervals each of which is smaller than the lifespan of booster 25 operating at any single wavelength.

As FIG. 8 illustrates, the useful life of booster 25 of the inventive system 15 is more than 4 times than that of the same booster shown in FIG. 3. Obviously, the useful life of booster 25 can last even longer than the one shown in FIG. 8 and be 10 times longer than the life of booster 25 of the known prior art. The increased useful life of booster 25 does not affect the output IR and/or Green light powers of system 15 of FIG. 7 which remains close to the desired maximum power varying within a ±(5-10)% range of its maximum.

Typically, the lifespan of booster 25 is determined in the following manner. The desired length of the available active fiber, i.e., a fiber doped with ions of any of the known rare earth elements with the known emission spectrum, is unwound off a new spool of fiber, and then cut to be a part of the experimental booster. The latter undergoes extensive testing procedure known to one of ordinary skill as burning during which the booster operates at any single wavelength selected from desired spectral range. The lifespan is thus experimentally determined. As known, it is difficult to achieve the fiber uniformity from one spool to another which necessitates establishing the time threshold for each new spool.

FIG. 9 illustrates the process of calibrating the operation of booster 25 based on the IR output power which is measured as a function of multiple seed center wavelengths corresponding to respective temperatures at multiple time points during burning of the booster. For example, two 1063.6 and 1065 nm operating wavelengths are selected. Assuming a 1 kW IR output is optimal, it is easy to see that booster 25 initially maintains the desired wattage over the desired spectral range of operating wavelengths, as indicated by a red curve, for the first 448-hour time interval which is shorter than the determined lifespan of the booster (500 hours.) During the following 400-hour time interval corresponding to a blue curve, the output power slightly drops at the 1063.6 nm wavelength. However, the losses at the operating 1063.6 nm wavelength remain within the desired power range, such as 5% and are thus acceptable. The output power remains practically optimal at the 1065 nm operating wavelength. The booster thus can function at the selected two operating wavelengths for the third 400-hour time interval which corresponds to the green curve. Assuming that the 10% loss at the operating 106.3 nm wavelength is unacceptable, the remaining 1065 wavelength is the only one operating wavelength that can be used for the booster's operation over the next 400-hour time interval corresponding to the purple curve. However, at the end of this time interval, the booster's output power is beyond the acceptable power range and needs to be replaced. Summarizing the above, the booster can operate during the first time interval at, for example, the 1065 nm wavelength and then be switched to output radiation at the 1063.6 nm wavelength for the second time interval. Finally, the following wavelength change back to 1065 nm allows the booster to operate for the third time interval. Thus the useful life of the booster is increased from 500 hours of the predetermined lifespan to the 1232-hour useful life.

The testing procedure as exemplified above is systemized and tabulated. The example of calibrated table establishing the correspondence among the time, temperature and wavelength is stored in CS 30 of FIG. 7 and illustrated below.

TABLE II

| | | |
|---|---|---|
| Time₁ | Temperature₁ | Wavelength₁ |
| Time₂ | Temperature₂ | Wavelength₂ |
| Time₃ | Temperature₃ | Wavelength₃ |
| . | . | . |
| . | . | . |
| . | . | . |
| Timeₙ | Temperatureₙ | Wavelengthₙ |

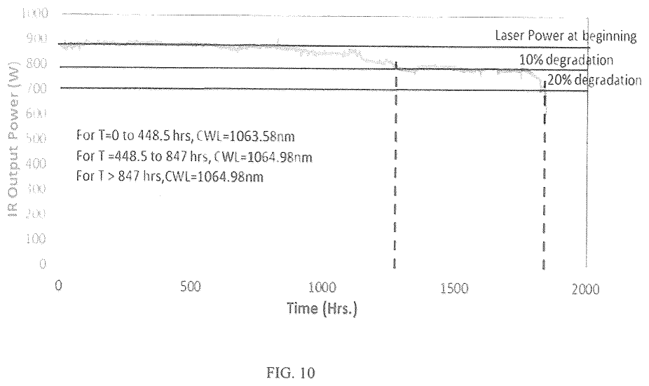

The time interval can be of any duration as long as it is shorter than the predetermined lifespan of the booster and does not necessarily be uniform. FIG. 10 is another example of the prolonged life of booster 25 of FIG. 7. As can be seen, both the IR and Green powers are within the desired power range for almost 1700 operating hours of booster 25 of FIG. 7. FIG. 9 illustrate the distribution of both average and peak powers of each of the IR and Green output. FIG. 10 illustrates the Green power distribution of laser system 15.

The aspects disclosed herein in accordance with the present invention, are not limited in their application to the details of construction and the arrangement of components set forth in the following description or illustrated in the accompanying drawings. These aspects are capable of assuming other optical schematics and of being practiced or of being carried out in various ways. Examples of specific implementations are provided herein for illustrative purposes only and are not intended to be limiting, in particular, acts, components, elements, and features discussed in connection with any one or more embodiments are not intended to be excluded from a similar role in any other embodiments. For example, booster 25 of FIG. 7 may operate in CW or pulsed regimes in addition to disclosed above QCW mode. Other operating parameters to be considered may include polarization, SM or MM, narrow/broad linewidth, single/multiple amplifying stages, dopant type, et cetera.

Having thus described several aspects of at least one example, one of ordinary skill in the art readily appreciates that various alterations, modifications, and improvements will readily occur to those skilled in the art. For instance, examples disclosed herein are applicable in other contexts. Such alterations, modifications, and improvements are part of this disclosure. Accordingly, the foregoing description and drawings are by way of example only.

1. A laser system comprising at least one light amplifying device which is configured to output a light signal at a first operating wavelength over a first time interval which is shorter than a predetermined lifespan of the light amplifying device, wherein the first operating wavelength is selected from a spectral range including a plurality of operating wavelengths at which the light amplifying device operates,
the light amplifying device being tunable to output the light signal at a second operating wavelength of the spectral range for a second time interval following the first time interval, wherein the second time interval is shorter than the predetermined lifespan of the light amplifying device.

2. The laser system of claim 1, wherein the one light amplifying device is a single mode (SM) or multimode (MM) oscillator.

3. The laser system of claim 1, wherein the one light amplifying device is a SM or MM amplifier, the system further comprising a SM or MM seed which sequentially generates the light signal at the first and second wavelengths, wherein the amplifier receives and outputs the light signal at a desired output power which remains within a specified power range for each time interval.

4. The laser system of claim 3, wherein the spectral range includes additional operating wavelengths at which the seed operates for respective additional time intervals each of which is shorter than the predetermined lifespan of the amplifier.

5. The laser system of claim 3, wherein the specified power range corresponds to ±5-10% of a maximum or optimal power, the spectral range being dependent on a configuration of the light amplifying device and dopant material.

6. The laser system of claim 3, wherein the oscillator is switchable among operating wavelengths at respective regular time intervals or irregular time intervals.

7. The laser system of claim 3 further comprising:
a thermo-electric cooler (TEC) coupled to and controlling a temperature of the seed, and
a controller operative to output a control signal which is coupled into and prompting the seed to switch among the operating wavelengths.

8. The laser system of claim 7, wherein the controller is configured with a memory device containing:
a temperature operating wavelength conversion table, the control system outputting the control signal coupled into the TEC at the end of each time interval so as to change the temperature of the oscillator in a stepwise manner, or
a continually optimizing algorithm for gradually changing the temperature of the oscillator during each of the time intervals so that an operating wavelength for each subsequent time interval is set at the end of the precedent time interval.

9. The laser system of claim 3 further comprising at least one or more fiber pre-amplifiers.

10. The laser system of claim 3, wherein the seed is selected from a narrow linewidth, broad linewidth, wavelength tunable, wavelength non-tunable, fiber, solid state, or single frequency oscillator, the amplifier being selected from a narrow linewidth, single frequency, wavelength tunable, wavelength non-tunable, fiber, solid state or hybrid amplifier.

11. The laser system of claim 3, wherein the seed and amplifier are each configured to output the light signal in a single mode or multiple modes.

12. The laser system of claim 3, wherein the oscillator and amplifier define as a master oscillator power amplifier architecture operating in a continuous wave or pulsed or quasi-continuous regime.

13. The laser system of claim 10, wherein the seed is temperature-based wavelength tunable or current-based wavelength tunable or temperature- and current-based tunable seed.

14. The laser system of claim 3 further comprising a frequency converter optically coupled to an output of the amplifier.

15. The laser system of claim 3, wherein the useful life of the amplifier is 3-10 times longer than the predetermined lifespan of the amplifier operating at one of the first and second wavelengths.

16. A method of operating a laser system having a seed and booster, comprising:
switching the seed between at least between two different operating wavelengths, which are selected from a desired spectral range, for respective time intervals which are shorter than a predetermined lifetime of the booster operating only at either one of the first and second wavelengths, thereby generating respective light signals; and
amplifying the light signals in the booster to provide a system output within a predetermined power range, wherein a total useful life of the booster operating at the first and second wavelengths is longer than the predetermined lifetime of the booster operating only at the first or second wavelength.

17. The method of claim 16, where the seed is switchable among first, second and at least one additional wavelengths selected from the spectral range, the predetermined lifetime of the booster being shorter than the useful life of the booster at the first, second and additional wavelengths.

18. The method of claim 16, wherein the predetermined power range varies within ±5-10% of a maximum or optimal power of the booster.

19. The method of claim 17, wherein the seed is switchable among operating wavelengths at respective regular time intervals or irregular time intervals.

20. The method of claim 18 further comprising controllably altering a temperature of the seed in accordance with a calibrated table establishing dependence of the operating wavelengths from respective temperatures or a continually wavelength-optimizing algorithm, wherein the seed is a laser diode or fiber oscillator.
